(19) United States
(12) Patent Application Publication
(10) Pub. No.: US 2024/0258219 A1
(43) Pub. Date: Aug. 1, 2024

(54) SEMICONDUCTOR DEVICE

(71) Applicant: Rohm Co., Ltd., Kyoto-shi (JP)

(72) Inventors: Ryotaro KAKIZAKI, Kyoto-shi (JP); Yasumasa KASUYA, Kyoto-shi (JP)

(21) Appl. No.: 18/630,588

(22) Filed: Apr. 9, 2024

Related U.S. Application Data
(63) Continuation of application No. PCT/JP2022/042573, filed on Nov. 16, 2022.

(30) Foreign Application Priority Data
Dec. 1, 2021 (JP) 2021-195177

(51) Int. Cl. H01L 23/498; H01L 23/00; H01L 23/31

(52) U.S. Cl. CPC H01L 23/49811; H01L 23/3121; H01L 23/49838; H01L 24/32; H01L 2224/32245; H01L 2924/1815

(57) ABSTRACT

A semiconductor device includes an element of semiconductor, first/second leads and a sealing resin. The first lead includes a die pad and a first terminal. The die pad includes a first lead obverse surface facing one side in thickness direction for mounting the element and a first lead reverse surface facing the other side in thickness direction. The sealing resin includes first/second resin surfaces respectively facing the one side and the other side in thickness direction. The sealing resin covers the element and a part of the die pad. The first lead reverse surface is exposed from the second resin surface. The second lead includes a second pad conducting to the element and a second terminal connected to the second pad. The second terminal includes a fourth portion connected to the second pad and a fifth portion on the one side in the thickness direction relative to the fourth portion.

### TECHNICAL FIELD

The present disclosure relates to a semiconductor device.

### BACKGROUND ART

JP-A-2017-174951 discloses an example of a conventional semiconductor device. The semiconductor device includes a first through a third leads, a semiconductor element, and a sealing resin. The first lead includes a first pad having a pad obverse surface and a pad reverse surface. The semiconductor element is mounted on the pad obverse surface. The sealing resin is in contact with the pad obverse surface and covers the semiconductor element. The first lead, the second lead and the third lead have a first terminal, a second terminal and a third terminal, respectively, that extend in the same direction. The semiconductor device is mounted on a circuit board or the like by inserting the first terminal, the second terminal and the third terminal into through-holes of the circuit board. When the semiconductor device is attached to a heat sink, an insulating sheet, for example, is placed between the pad reverse surface and the heat sink.

### BRIEF DESCRIPTION OF THE DRAWINGS

FIG. 1 is a perspective view of a semiconductor device according to a first embodiment of the present disclosure.

FIG. 2 is a perspective view of the semiconductor device according to the first embodiment of the present disclosure.

FIG. 3 is a perspective view of the semiconductor device according to the first embodiment of the present disclosure.

FIG. 4 is a perspective view showing relevant portions of the semiconductor device according to the first embodiment of the present disclosure.

FIG. 5 is a perspective view showing relevant portions of the semiconductor device according to the first embodiment of the present disclosure.

FIG. 6 is a plan view of the semiconductor device according to the first embodiment of the present disclosure.

FIG. 7 is a bottom view of the semiconductor device according to the first embodiment of the present disclosure.

FIG. 8 is a front view of the semiconductor device according to the first embodiment of the present disclosure.

FIG. 9 is a side view of the semiconductor device according to the first embodiment of the present disclosure.

FIG. 10 is a plan view showing relevant portions of the semiconductor device according to the first embodiment of the present disclosure.

FIG. 11 is a bottom view showing relevant portions of the semiconductor device according to the first embodiment of the present disclosure.

FIG. 12 is a sectional view taken along line XII-XII in FIG. 11.

FIG. 13 is a sectional view taken along line XIII-XIII in FIG. 11.

FIG. 14 is a sectional view taken along line XIV-XIV in FIG. 11.

FIG. 15 is a sectional view showing a use state of the semiconductor device according to the first embodiment of the present disclosure.

FIG. 16 is a sectional view showing a first variation of the semiconductor device according to the first embodiment of the present disclosure.

FIG. 17 is a sectional view showing a use state of the first variation of the semiconductor device according to the first embodiment of the present disclosure.

FIG. 18 is a perspective view showing a second variation of the semiconductor device according to the first embodiment of the present disclosure.

FIG. 19 is a sectional view showing the second variation of the semiconductor device according to the first embodiment of the present disclosure.

FIG. 20 is a perspective view showing a third variation of the semiconductor device according to the first embodiment of the present disclosure.

FIG. 21 is a sectional view showing the third variation of the semiconductor device according to the first embodiment of the present disclosure.

FIG. 22 is a perspective view showing a fourth variation of the semiconductor device according to the first embodiment of the present disclosure.

FIG. 23 is a sectional view showing the fourth variation of the semiconductor device according to the first embodiment of the present disclosure.

FIG. 24 is a sectional view showing a fifth variation of the semiconductor device according to the first embodiment of the present disclosure.

FIG. 25 is a side view showing a sixth variation of the semiconductor device according to the first embodiment of the present disclosure.

FIG. 26 is a plan view showing relevant portions of a semiconductor device according to a second embodiment of the present disclosure.

FIG. 27 is a plan view showing relevant portions of a semiconductor device according to a third embodiment of the present disclosure.

FIG. 28 is a sectional view of a semiconductor device according to a fourth embodiment of the present disclosure.

FIG. 29 is a sectional view of a semiconductor device according to a fifth embodiment of the present disclosure.

FIG. 30 is a perspective view of a semiconductor device according to a sixth embodiment of the present disclosure.

FIG. 31 is a plan view showing relevant portions of the semiconductor device according to the sixth embodiment of the present disclosure.

FIG. 32 is a perspective view showing a variation of the semiconductor device according to the sixth embodiment of the present disclosure.

FIG. 33 is a sectional view of a semiconductor device according to a seventh embodiment of the present disclosure.

FIG. 34 is a sectional view showing a variation of the semiconductor device according to the seventh embodiment of the present disclosure.

### DETAILED DESCRIPTION OF EMBODIMENTS

The following describes preferred embodiments of the present disclosure in detail with reference to the drawings. The terms “first”, “second”, “third”, and the like in the present disclosure are used merely for identification, and are not intended to order these subjects.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”.

### First Embodiment

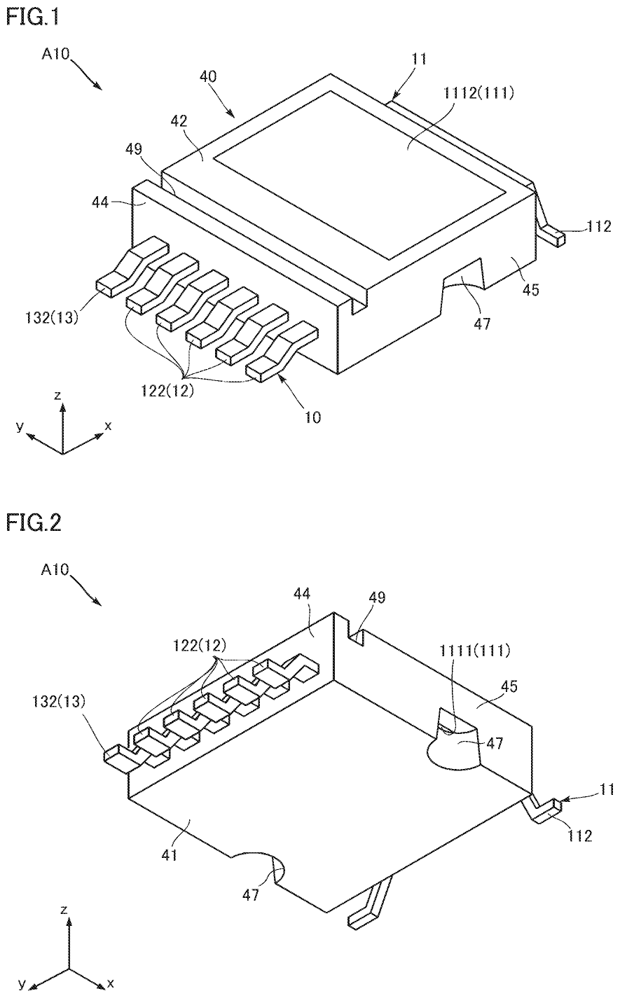

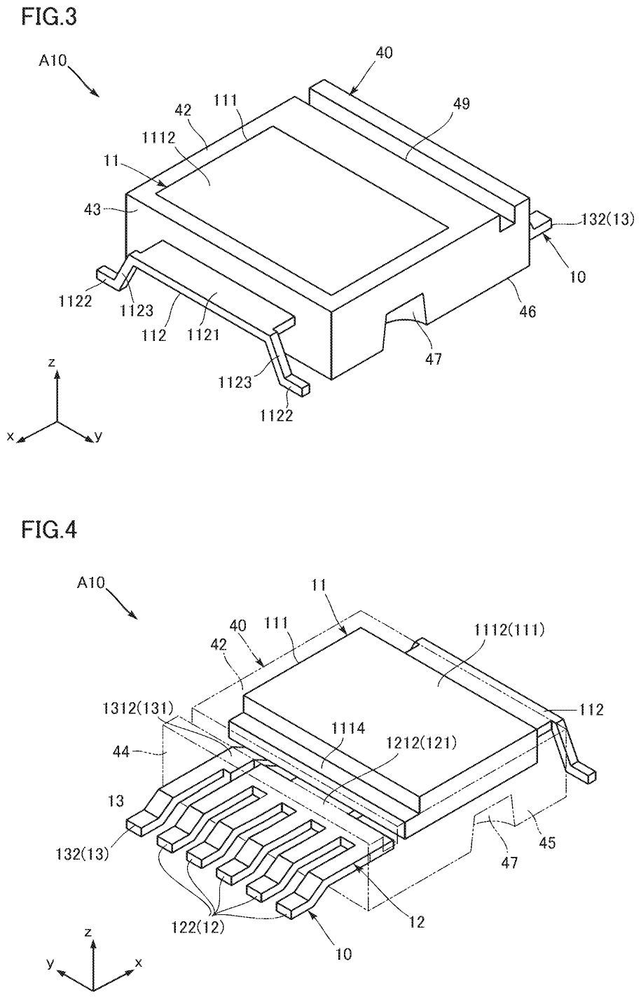

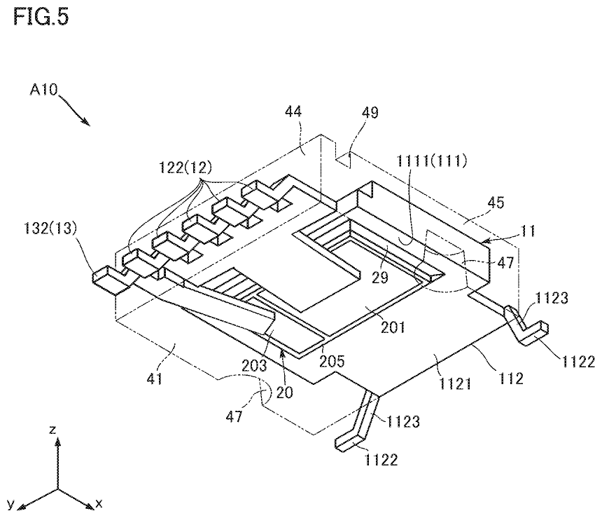

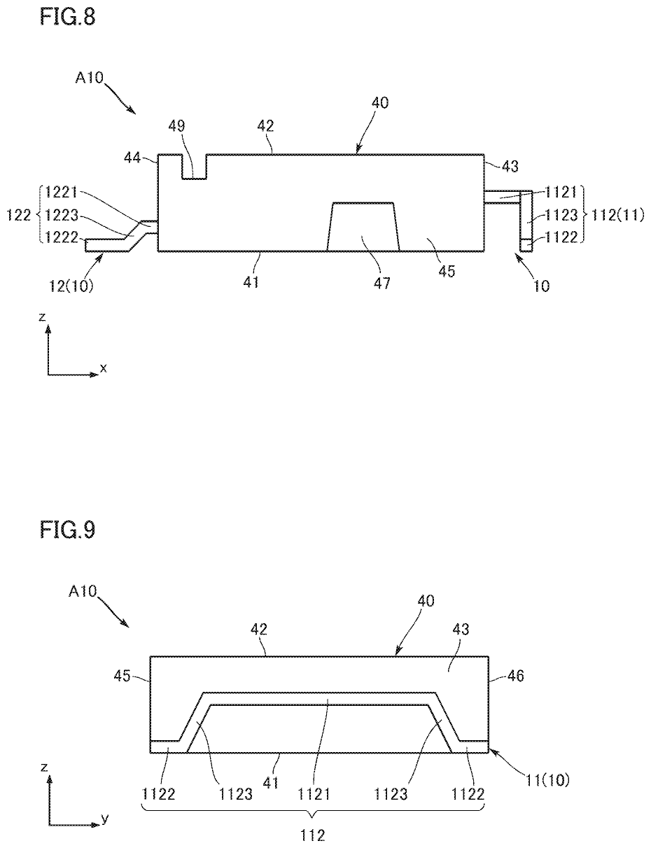

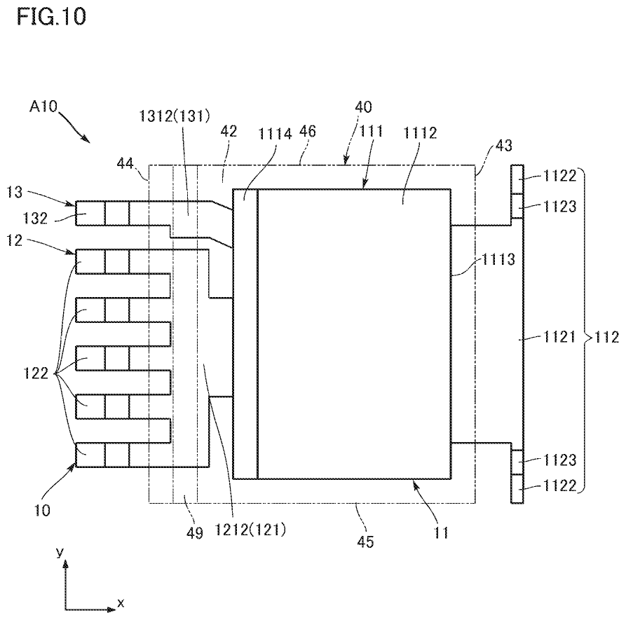

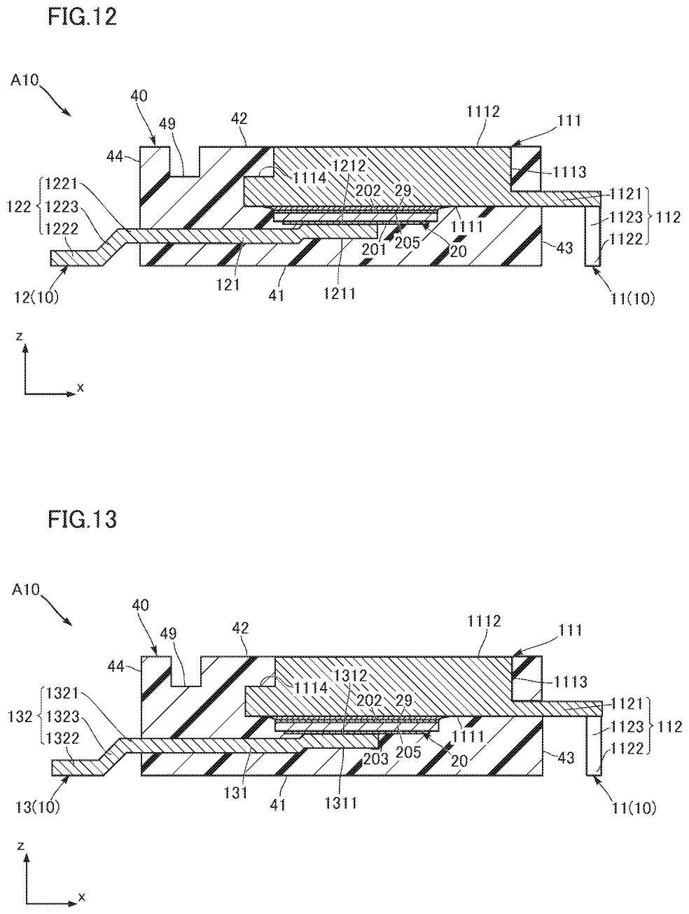

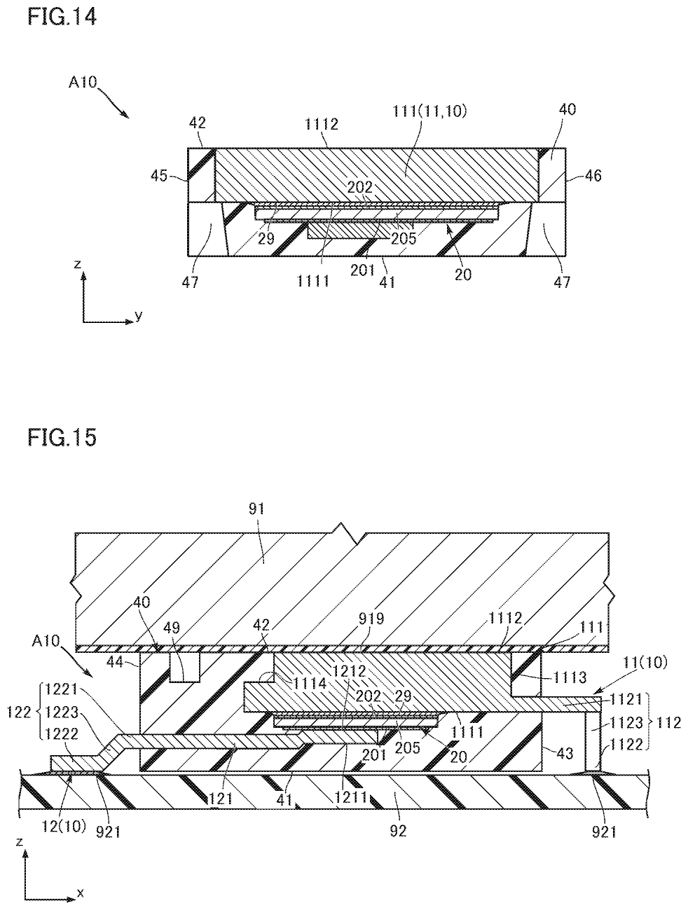

FIGS. 1 to 15 show a semiconductor device according to a first embodiment of the present disclosure. The semiconductor device A10 of the present embodiment includes a conductive member 10, a semiconductor element 20, and a sealing resin 40. In these figures, the z direction is an example of “thickness direction”, the x direction is an example of “first direction”, and the y direction is an example of “second direction”.

### Conductive Member 10:

The conductive member 10 is a member that forms conduction paths to the semiconductor element 20. The conductive member 10 of the present embodiment includes a first lead 11, a second lead 12, and a third lead 13. The material of the first lead 11, the second lead 12 and the third lead 13 is not limited and may include copper (Cu) or a copper alloy, for example. The first lead 11, the second lead 12, and the third lead 13 may be plated with, for example, silver (Ag), nickel (Ni) or tin (Sn) at appropriate locations.

### First Lead 11:

As shown in FIGS. 1 to 14, the first lead 11 has a die pad portion 111 and a first terminal portion 112. The die pad portion 111 has a first lead obverse surface 1111 and a first lead reverse surface 1112. The first lead obverse surface 1111 faces a first side in the z direction. The first lead reverse surface 1112 faces a second side in the z direction. The semiconductor element 20 is mounted on the first lead obverse surface 1111.

The die pad portion 111 of the present embodiment further has a first lead side surface 1113 and a first intermediate surface 1114. The first lead side surface 1113 is located between the first lead obverse surface 1111 and the first lead reverse surface 1112 in the z direction and faces a first side in the x direction. The first intermediate surface 1114 is located between the first lead obverse surface 1111 and the first lead reverse surface 1112 in the z direction and faces the second side (the same side as the side that the first lead reverse surface 1112 faces) in the z direction.

The shape of the die pad portion 111 is not limited. In the illustrated example, the die pad portion 111 is rectangular as viewed in the z direction. Also, the shape of the first lead obverse surface 1111 and the first lead reverse surface 1112 is not limited and is rectangular as viewed in the z direction in the illustrated example.

The first terminal portion 112 has a first portion 1121, two second portions 1122, and two third portions 1123. The first portion 1121 is connected to the die pad portion 111, extends from the die pad portion 111 toward the first side in the x direction, and is parallel to the xy-plane in the illustrated example. In the present embodiment, the die pad portion 111 is larger than the first portion 1121 in size in the z direction. The first terminal portion 112 of the present embodiment has only one first portion 1121. The shape of the first portion 1121 is not limited and is rectangular as viewed in the z direction in the illustrated example. The first portion 1121 is spaced apart from the first lead reverse surface 1112 in the z direction and is in contact with the first lead obverse surface 1111 in the illustrated example. The surface of the first portion 1121 on the first side in the z direction is flush with the first lead obverse surface 1111.

The two second portions 1122 are located on the first side in the z direction with respect to the first portion 1121. The two second portions 1122 are used in surface-mounting the semiconductor device A10 to a circuit board or the like.

The two third portions 1123 are interposed between the first portion 1121 and the two second portions 1122. The third portions 1123 extend from the first portion 1121 toward the first side in the z direction. In the illustrated example, the third portions 1123 are inclined with respect to the z direction in such a manner that they extend from the first portion 1121 outward in the y direction. The shape of the third portions 1123 is not limited and is rectangular as viewed in the y direction in the illustrated example.

In the present embodiment, the two second portions 1122 extend from the two third portions 1123 outward in the y direction. The two second portions 1122 are parallel to the y direction. The two second portions 1122 do not protrude from the two third portions 1123 toward the first side in the x direction. In the illustrated example, the two second portions 1122 and the two third portions 1123 are at the same position in the x direction.

### Second Lead 12:

The second lead 12 is spaced apart from the first lead 11. The second lead 12 is located on the first side in the z direction of the die pad portion 111 and located on a second side in the x direction with respect to the first terminal portion 112 of the first lead 11. The second lead 12 has a second pad portion 121 and a plurality of second terminal portions 122.

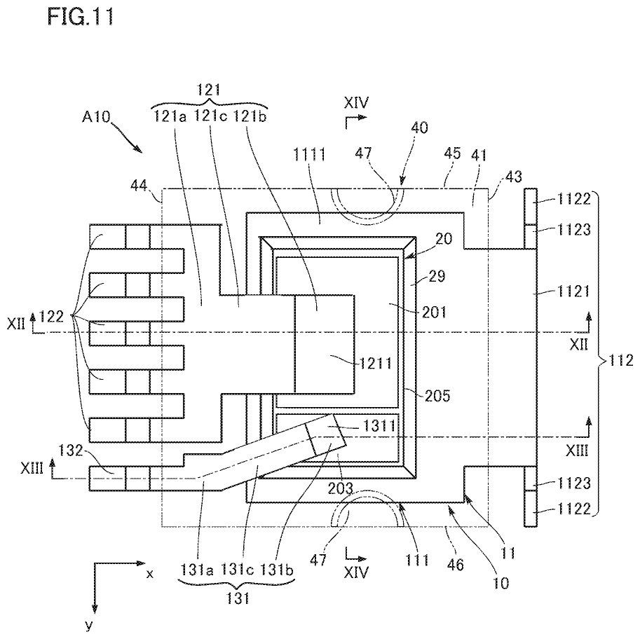

The second pad portion 121 has a second lead obverse surface 1211 and a second lead reverse surface 1212. The second lead obverse surface 1211 faces the first side in the z direction. The second lead reverse surface 1212 faces the second side in the z direction. The second lead reverse surface 1212 is conductively bonded to the first electrode 201, described later, of the semiconductor element 20. The second lead reverse surface 1212 and the first electrode 201 are bonded together via solder, for example. The second lead reverse surface 1212 and the first electrode 201 may be bonded together via silver (Ag) paste or sintered silver, for example. The shape of the second pad portion 121 is not limited. In the illustrated example, the second pad portion 121 has a main body 121a, a bonded portion 121b, and a connecting portion 121c, as shown in FIG. 11. The main body 121a has a rectangular shape elongated in the y direction, and the second terminal portions 122 are connected to the main body. The bonded portion 121b is rectangular and conductively bonded to the first electrode 201 of the semiconductor element 20. The connecting portion 121c is rectangular and connected to the main body 121a and the bonded portion 121b. In the present embodiment, the bonded portion 121b is located on the second side in the z direction from the main body 121a. As viewed in the z direction, the second pad portion 121 is smaller than the die pad portion 111. The size of the second pad portion 121 in the z direction is smaller than that of the die pad portion 111 and the same as that of the first terminal portion 112.

The second terminal portions 122 are arranged side by side in the y direction. Each of the second terminal portions 122 has a fourth portion 1221, a fifth portion 1222, and a sixth portion 1223.

The fourth portion 1221 is connected to the second pad portion 121, extends from the second pad portion 121 toward the second side in the x direction, and is parallel to the xy-plane in the illustrated example. The shape of the fourth portion 1221 is not limited and is rectangular as viewed in the z direction in the illustrated example.

The fifth portion 1222 is located on the first side in the z direction with respect to the fourth portion 1221. The used in surface-mounting the fifth portion 1222 is semiconductor device A10 to a circuit board or the like. The fifth portion 1222 extends along the x direction.

The sixth portion 1223 is interposed between the fourth portion 1221 and the fifth portion 1222. The sixth portion 1223 extends from the fourth portion 1221 toward the first side in the z direction. In the illustrated example, the sixth portion 1223 is inclined with respect to the z direction (yz-plane). The shape of the sixth portion 1223 is not limited and is rectangular as viewed in the x direction in the illustrated example.

### Third Lead 13:

The third lead 13 is spaced apart from the first lead 11 and the second lead 12. The third lead 13 is located on the first side in the z direction of the die pad portion 111 and located on the second side in the x direction with respect to the first terminal portion 112 of the first lead 11. The third lead 13 is aligned with the second lead 12 in the y direction. The third lead 13 has a third pad portion 131 and a third terminal portion 132.

The third pad portion 131 has a third lead obverse surface 1311 and a third lead reverse surface 1312. The third lead obverse surface 1311 faces the first side in the z direction. The third lead reverse surface 1312 faces the second side in the z direction. The third lead reverse surface 1312 is conductively bonded to the third electrode 203, described later, of the semiconductor element 20. The third lead reverse surface 1312 and the third electrode 203 are bonded together via solder, for example. The third lead reverse surface 1312 and the third electrode 203 may be bonded together via silver (Ag) paste or sintered silver, for example. The shape of the third pad portion 131 is not limited. In the illustrated example, the third pad portion 131 has a main body 131a, a bonded portion 131b, and a connecting portion 131c, as shown in FIG. 11. The main body 131a is rectangular, and the third terminal portion 132 is connected to the main body. The bonded portion 131b is rectangular and conductively bonded to the third electrode 203 of the semiconductor element 20. The connecting portion 131c has the shape of an elongated rectangle and is connected to the main body 131a and the bonded portion 131b. In the present embodiment, the connecting portion 131c extends obliquely with respect to the x direction. The bonded portion 131b is located on the second side in the z direction from the main body 131a. As viewed in the z direction, the third pad portion 131 is smaller than the second pad portion 121. The size of the third pad portion 131 in the z direction is smaller than that of the die pad portion 111 and the same as that of the second pad portion 121.

The third terminal portion 132 has a seventh portion 1321, an eighth portion 1322, and a ninth portion 1323.

The seventh portion 1321 is connected to the third pad portion 131, extends from the third pad portion 131 toward the second side in the x direction, and is parallel to the xy-plane in the illustrated example. The shape of the seventh portion 1321 is not limited and is rectangular as viewed in the z direction in the illustrated example.

The eighth portion 1322 is located on the first side in the z direction with respect to the seventh portion 1321. The eighth portion 1322 is used in surface-mounting the semiconductor device A10 to a circuit board or the like. The eighth portion 1322 extends along the x direction.

The ninth portion 1323 is interposed between the seventh portion 1321 and the eighth portion 1322. The ninth portion 1323 extends from the seventh portion 1321 toward the first side in the z direction. In the illustrated example, the ninth portion 1323 is inclined with respect to the z direction (yz-plane). The shape of the ninth portion 1323 is not limited and is rectangular as viewed in the x direction in the illustrated example.

### Semiconductor Element 20:

As shown in FIGS. 5 and 11 to 14, the semiconductor element 20 is mounted on the first lead obverse surface 1111 of the die pad portion 111. In the semiconductor device A10, the semiconductor element 20 is an n-channel MOSFET (Metal-Oxide-Semiconductor Field-Effect Transistor) of a vertical structure type. The semiconductor element 20 is not limited to a MOSFET. The semiconductor element 20 may be other transistors such as an IGBT (Insulated Gate Bipolar Transistor). The semiconductor element 20 may be a diode. The semiconductor element 20 has a semiconductor layer 205, the first electrode 201, a second electrode 202, and the third electrode 203.

The semiconductor layer 205 includes a compound semiconductor substrate. The main material of the compound semiconductor substrate is silicon carbide (Sic). Alternatively, silicon (Si) may be used as the main material of the compound semiconductor substrate.

The first electrode 201 is provided on the side (the first side) in the z direction that the first lead obverse surface 1111 of the die pad portion 111 of the first lead 11 faces. The first electrode 201 corresponds to the source electrode of the semiconductor element 20.

The second electrode 202 is provided opposite to the first electrode 201 in the z direction. The second electrode 202 faces the first lead obverse surface 1111 of the die pad portion 111 of the first lead 11. The second electrode 202 corresponds to the drain electrode of the semiconductor element 20. In the present embodiment, the second electrode 202 is conductively bonded to the first lead obverse surface 1111 via a bonding layer 29. The bonding layer 29 is, for example, solder, silver (Ag) paste, sintered silver or the like.

The third electrode 203 is provided on the same side as the first electrode 201 in the z direction and spaced apart from the first electrode 201. The third electrode 203 corresponds to the gate electrode of the semiconductor element 20. As viewed in the z direction, the area of the third electrode 203 is smaller than the area of the first electrode 201.

In the present embodiment, the first terminal portion 112 of the first lead 11 is a drain terminal, the second terminal portions 122 of the second lead 12 are source terminals, and the third terminal portion 132 of the third lead 13 is a gate terminal.

### Sealing Resin 40:

As shown in FIGS. 1 to 14, the sealing resin 40 covers the semiconductor element 20, and a portion of each of the first lead 11, the second lead 12 and the third lead 13. The sealing resin 40 has an electrically insulating property. The sealing resin 40 is made of a material containing a black epoxy resin, for example. The sealing resin 40 has a first resin surface 41, a second resin surface 42, a third resin surface 43, a fourth resin surface 44, a fifth resin surface 45, and a sixth resin surface 46.

The first resin surface 41 faces the same side (the first side) as the side that the first lead obverse surface 1111 of the die pad portion 111 of the first lead 11 faces in the z direction. The second resin surface 42 faces a side (the second side) opposite to the side that the first resin surface 41 faces in the z direction. The first lead reverse surface 1112 of the die pad portion 111 of the first lead 11 is exposed from the second resin surface 42. The second resin surface 42 and the first lead reverse surface 1112 are flush with each other. The first lead reverse surface 1112 is spaced apart from the third resin surface 43 in the x direction.

The third resin surface 43 faces the first side in the x direction. The first portion 1121 of the first terminal portion 112 of the first lead 11 penetrates the third resin surface 43. In the present embodiment, the single first portion 1121 penetrates the third resin surface 43. The first portion 1121 is spaced apart from the second resin surface 42 in the z direction.

The fourth resin surface 44 faces a side (the second side) opposite to the side that the third resin surface 43 faces in the x direction. In the present embodiment, the fourth portions 1221 of the second terminal portions 122 of the second lead 12 and the seventh portion 1321 of the third terminal portion 132 of the third lead 13 penetrate the fourth resin surface 44. The fourth portion 1221 and the seventh portion 1321 are spaced apart from the second resin surface 42 in the z direction.

The fifth resin surface 45 and the sixth resin surface 46 face mutually opposite sides in the y direction.

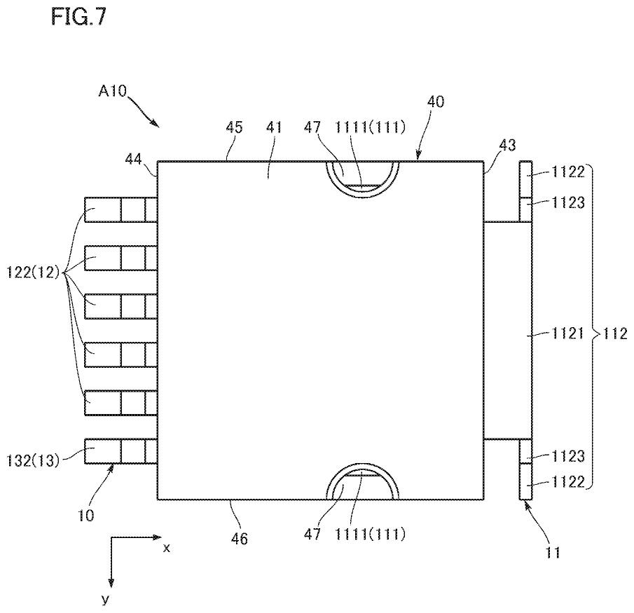

As shown in FIG. 7, the ends in the y direction of the two second portions 1122 of the first terminal portion 112 of the first lead 11 are at approximately the same position as the fifth resin surface 45 and the sixth resin surface 46 of the sealing resin 40 in the y direction. The two second portions 1122 do not protrude from the fifth resin surface 45 and the sixth resin surface 46 in the y direction.

In the illustrated example, the sealing resin 40 has a groove 49. The groove 49 is recessed from the second resin surface 42 in the z direction and extends along the y direction. The groove 49 reaches the fifth resin surface 45 and the sixth resin surface 46.

In the illustrated example, the sealing resin 40 also has two recesses 47. One of the recesses 47 is recessed from the first resin surface 41 and the fifth resin surface 45. The other recess 47 is recessed from the first resin surface 41 and the sixth resin surface 46. Portions of the first lead obverse surface 1111 are exposed from the recesses 47.

FIG. 15 shows the semiconductor device A10 in use. In this example of use, the semiconductor device A10 is surface-mounted on a circuit board 92. Specifically, the second portions 1122 of the first terminal portion 112, the fifth portions 1222 of the second terminal portions 122, and the eighth portion 1322 of the third terminal portion 132 are conductively bonded to a wiring pattern (not shown) of the circuit board 92 with solder 921, for example. Also, a heat sink 91 is placed to face the first lead reverse surface 1112 of the die pad portion 111. In the illustrated example, a sheet material 919 is disposed between the first lead reverse surface 1112 and the heat sink 91. The sheet material 919 may be an insulating sheet, for example.

Next, the effects of the semiconductor device A10 will be described.

As shown in FIG. 15, the first lead reverse surface 1112 is exposed from the second resin surface 42. This allows, for example, the heat sink 91 to be placed to face the first lead reverse surface 1112. The second portions 1122 are located on the first side in the z direction from the first portion 1121. Thus, the semiconductor device A10 can be surface-mounted to the circuit board 92 or the like using the second portions 1122. The first lead reverse surface 1112 is spaced apart from the third resin surface 43 in the x direction. Also, the first portion 1121 is spaced apart from the second resin surface 42 in the z direction. With such a configuration, a portion of the sealing resin 40 exists between the first lead reverse surface 1112 and the first portion 1121. As a result, the first lead 11 is firmly held by the sealing resin 40.

The second lead reverse surface 1212 is conductively bonded to the first electrode 201 of the semiconductor element 20. Also, the third lead reverse surface 1312 is conductively bonded to the third electrode 203 of the semiconductor element 20. This allows a larger current to flow as compared with the case where the second lead 12 (third lead 13) and the first electrode 201 (third electrode 203) are conductively connected via a bonding wire. Additionally, the number of parts of the semiconductor device A10 can be reduced as compared with the case where the second lead 12 (third lead 13) and the first electrode 201 (third electrode 203) are conductively connected via a metal plate (clip).

The first terminal portion 112 has the third portion 1123. This allows the second portion 1122 to be supported more reliably.

The third portion 1123 is parallel to the yz-plane. Thus, the dimension in the x direction of the semiconductor device A10 is reduced.

The first terminal portion 112 has two second portions 1122. This increases the mounting strength of the semiconductor device A10.

The two second portions 1122 extend from the third portions 1123 outward in the y direction. This further increases the mounting strength of the semiconductor device A10.

The size of the first portion 1121 in the y direction is smaller than the size of the die pad section 111 in the y direction. This further enhances the holding of the first lead 11 by the sealing resin 40.

The second portions 1122 do not protrude from the third portion 1123 in the x direction. This reduces the dimension in the x direction of the semiconductor device A10.

The die pad portion 111 is larger than the first portion 1121 in size in the z direction. With such a configuration, during the process of heat transfer from the semiconductor element 20 to the first lead reverse surface 1112, the heat can be transferred to a wider area in the x direction and the y direction. As a result, the heat from the semiconductor element 20 can be dissipated to the heat sink 91 or the like through a wider area of the first lead reverse surface 1112, which enhances the heat dissipation efficiency.

The surface of the first portion 1121 on the first side in the z direction is flush with the first lead obverse surface 1111. This increases the distance from the first portion 1121 to the second resin surface 42 in the z direction and further enhances the holding of the first lead 11 by the sealing resin 40.

The sealing resin 40 is formed with the groove 49. This increases the distance along the surface of the sealing resin 40 (hereinafter “creepage distance”) from the first lead reverse surface 1112 to the second lead 12 (fourth portion 1221) and the third lead 13 (seventh portion 1321).

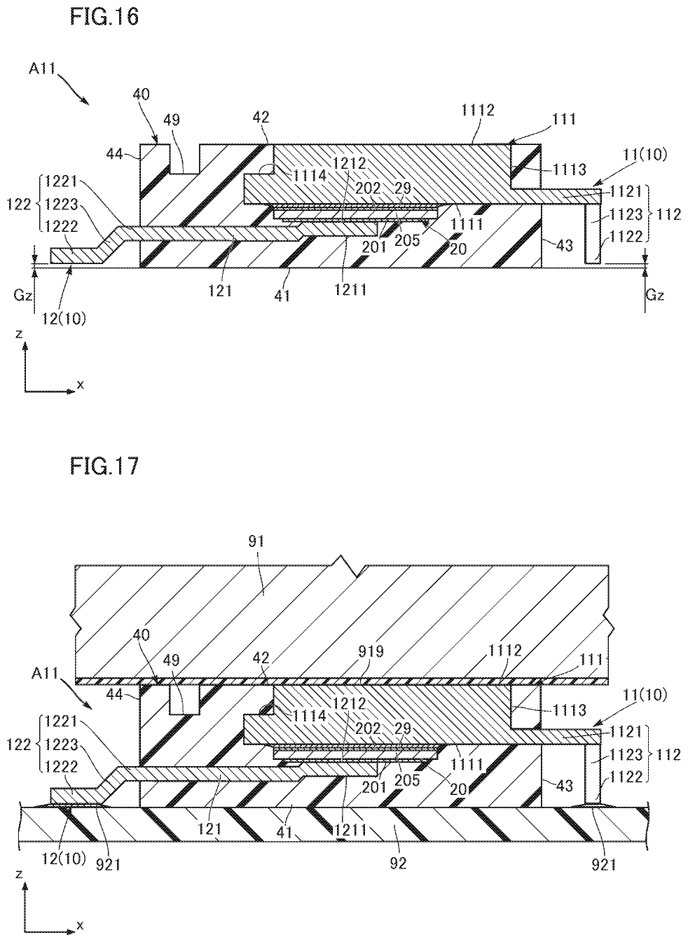

FIGS. 16 to 34 show other embodiments of the present disclosure. In these figures, the elements that are identical or similar to those of the above-described embodiment are denoted by the same reference signs as those of the above-described embodiments. Various parts of variations and embodiments may be selectively used in any appropriate combination as long as it is technically compatible.

### First Embodiment, First Variation

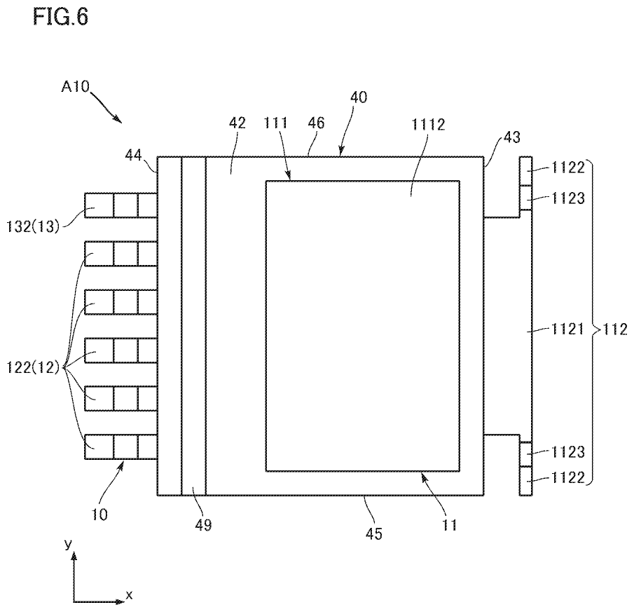

FIGS. 6 and 17 show a first variation of the semiconductor device A10. The semiconductor device A11 of the present variation differs from the above-described example in relationship between the second portion 1122, the fifth portion 1222 and the eighth portion 1322, and the first resin surface 41.

In the present variation, the second portion 1122, the fifth portion 1222 and the eighth portion 1322 are located on the second side in the z direction (the side that the first lead reverse surface 1112 faces) from the first resin surface 41. The surfaces of the second portion 1122, the fifth portion 1222 and the eighth portion 1322 that face the first side in the z direction and the first resin surface 41 are spaced apart from each other by a distance Gz.

According to the present variation again, the semiconductor device A11 can be surface-mounted, and the same effects as those of the semiconductor device A10 are provided. The first resin surface 41 protrudes toward the first side in the z direction by the distance Gz relative to the second portion 1122, the fifth portion 1222 and the eighth portion 1322. Therefore, in the use state of the semiconductor device A11 shown in FIG. 17, when the heat sink 91 is pressed against the semiconductor device A11, the first resin surface 41 tends to come into contact with the circuit board 92. This reduces the likelihood that the force applied from the heat sink 91 acts on the first lead 11, the second lead 12 and the third lead 13, or the semiconductor element 20.

### First Embodiment, Second Variation

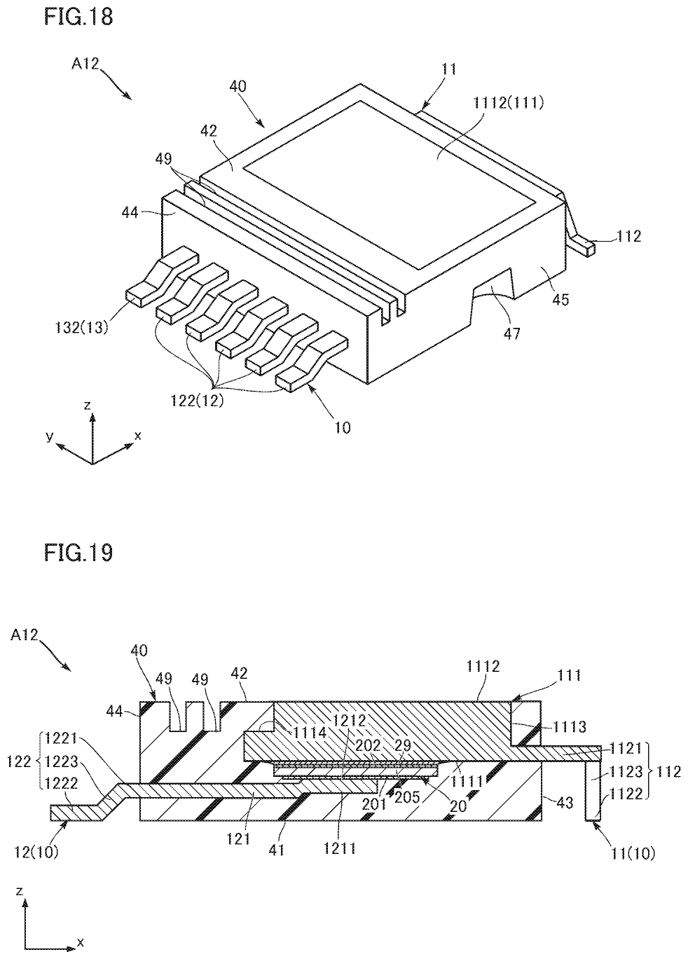

FIGS. 18 and 19 show a second variation of the semiconductor device A10. In the semiconductor device A12 of the present variation, the sealing resin 40 is provided with two grooves 49.

Each groove 49 extends in the y direction and reaches the fifth resin surface 45 and the sixth resin surface 46. The two grooves 49 are spaced apart from each other in the x direction.

According to the present variation again, the semiconductor device A12 can be surface-mounted, and the same effects as those of the above-described examples are provided. Additionally, having two grooves 49 further increases the creepage distance between the first lead reverse surface 1112 and the second and the third terminal portions 122 and 132. As will be understood from the present variation, the number of grooves 49 is not limited.

### First Embodiment, Third Variation

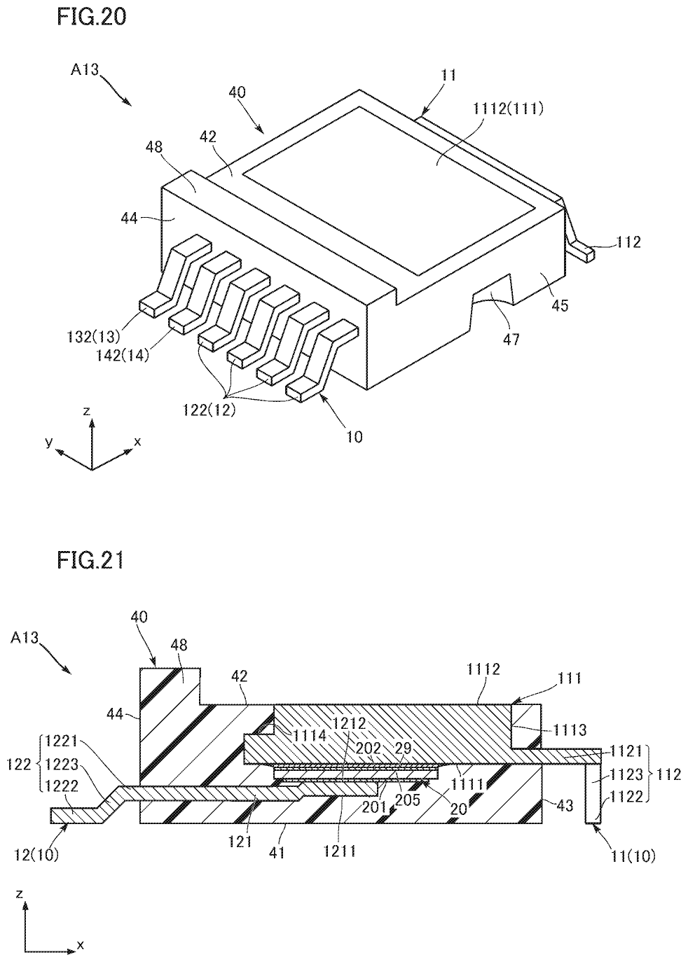

FIGS. 20 and 21 show a third variation of the semiconductor device A10. In the semiconductor device A13 of the present variation, the sealing resin 40 is provided with a protrusion 48.

The protrusion 48 protrudes from the second resin surface 42 toward the second side in the z direction. The protrusion 48 extends along the y direction and reaches the fifth resin surface 45 and the sixth resin surface 46. In the illustrated example, the protrusion 48 is located at the end on the second side in the x direction of the sealing resin 40 and in contact with the fourth resin surface 44.

According to present variation again, the semiconductor device A13 can be surface-mounted. Additionally, having the protrusion 48 increases the creepage distance between the first lead reverse surface 1112 and the second and the third terminal portions 122 and 132.

### First Embodiment, Fourth Variation

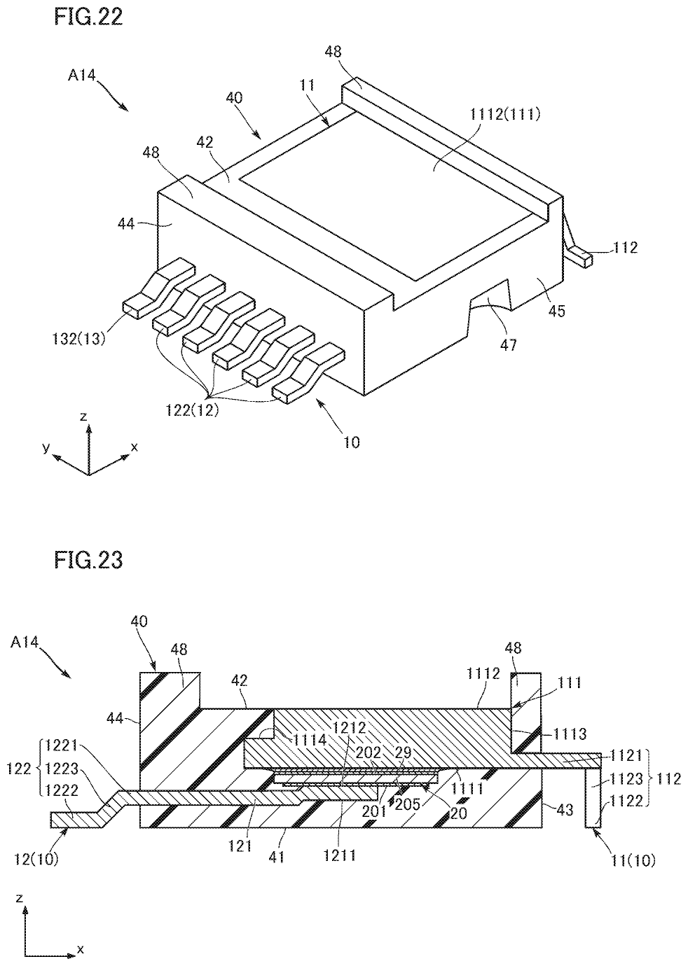

FIGS. 22 and 23 show a fourth variation of the semiconductor device A10. In the semiconductor device A14 of the present variation, the sealing resin 40 is provided with two protrusions 48.

Both protrusions 4 protrude from the second resin surface 42 toward the second side in the z direction. Each protrusion 48 extends along the y direction and reaches the fifth resin surface 45 and the sixth resin surface 46. The two protrusions 48 are spaced apart from each other with the first lead reverse 1112 therebetween in the X surface direction. One of the protrusions 48 is in contact with the fourth resin surface 44. The other protrusion 48 is in contact with the third resin surface 43.

According to the present variation again, the semiconductor device A14 can be surface-mounted. Additionally, having two protrusions 48 further increases the creepage distance between the first lead reverse surface 1112 and the second and the third terminal portions 122 and 132. As will be understood from the present variation, the number of protrusions 48 is not limited.

### First Embodiment, Fifth Variation

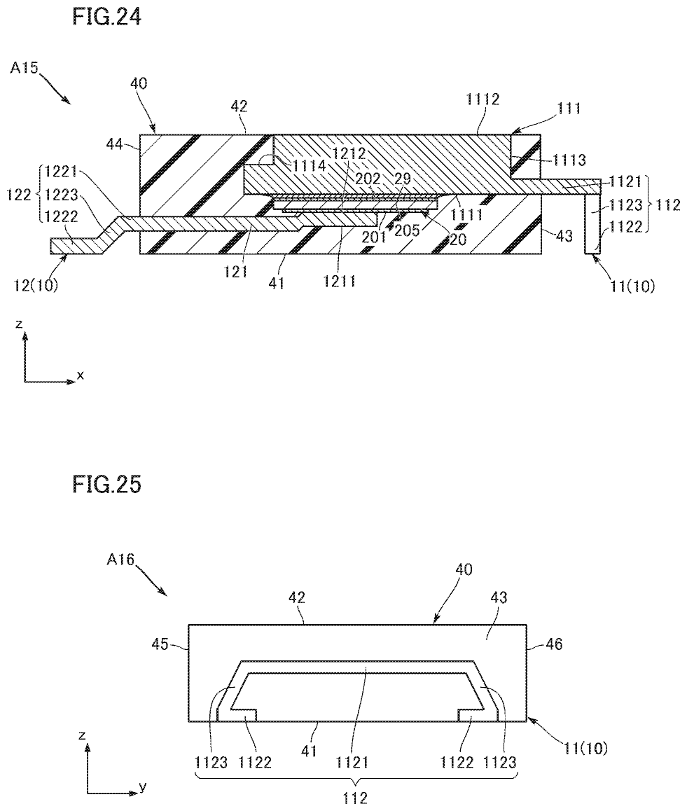

FIG. 24 shows a fifth variation of the semiconductor device A10. In the semiconductor device A15 of the present variation, the sealing resin 40 does not have the protrusion 48 and the groove 49 described above. According to the present variation again, the semiconductor device A15 can be surface-mounted. As will be understood from the present variation, the sealing resin 40 may not have the protrusion 48 and the groove 49.

### First Embodiment, Sixth Variation

FIG. 25 shows a sixth variation of the semiconductor device A10. In the semiconductor device A16 of the present variation, the two second portions 1122 extend from the two third portions 1123 inward in the x direction. According to the present variation again, the semiconductor device A16 can be surface-mounted. As will be understood from the present variation, the shape or the like of the second portion 1122 is not limited.

### Second Embodiment

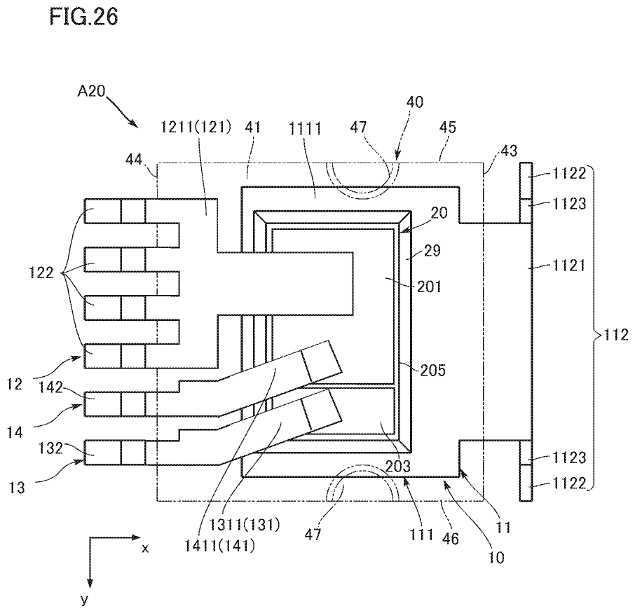

FIG. 26 shows a semiconductor device according to a second embodiment the of present disclosure. The semiconductor device A20 of the present embodiment differs from the first embodiment in that it further includes a fourth lead 14. The configuration and operation of other parts of the present embodiment are the same as those of the first embodiment. Incidentally, various parts of the first embodiment and the variations may be selectively used in an appropriate combination.

In the present embodiment, the fourth lead 14 is disposed between the second lead 12 and the third lead 13 in the y direction. The fourth lead 14 is spaced apart from the first lead 11, the second lead 12, and the third lead 13. The fourth lead 14 is located on the first side in the z direction of the die pad portion 111 and located on the second side in the x direction with respect to the first terminal portion 112 of the first lead 11. The fourth lead 14 has a fourth pad portion 141 and a fourth terminal portion 142.

The shape of the fourth pad portion 141 is not limited and may be similar to that of third pad portion 131. The fourth pad portion 141 has a fourth lead obverse surface 1411 and a fourth lead reverse surface 1412. The fourth lead obverse surface 1411 faces the first side in the z direction. The fourth lead reverse surface 1412 faces the second side in the z direction. The fourth lead reverse surface 1412 is conductively bonded to the first electrode 201 of the semiconductor element 20. The shape of the fourth terminal portion 142 is not limited and may be similar to that of the third terminal portion 132. The fourth terminal portion 142 of the fourth lead 14 is a source sense terminal.

According to the present variation again, the semiconductor device A20 can be surface-mounted. The fourth lead 14 may be disposed opposite to the third lead 13 with respect to the second lead 12 in the y direction.

### Third Embodiment

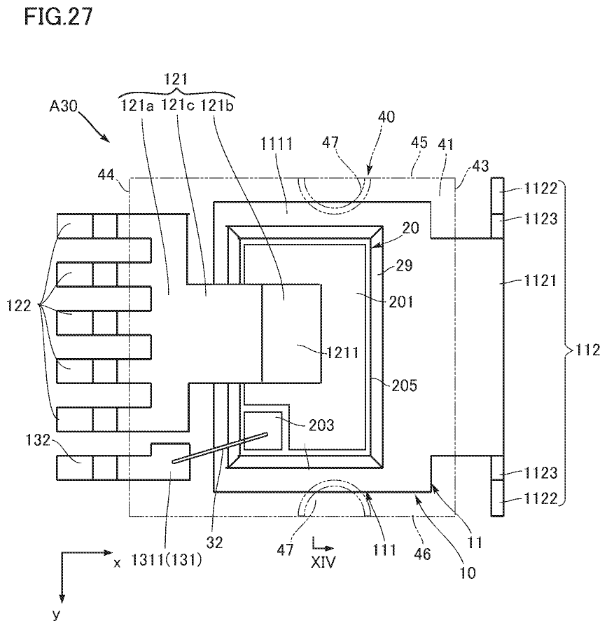

FIG. 27 shows a semiconductor device according to a third embodiment of the present disclosure. The semiconductor device A30 of the present embodiment differs from the first embodiment in configuration for conduction between the third lead 13 and the semiconductor element 20. The configuration and operation of other parts of the present embodiment are the same as those of the first embodiment. Incidentally, various parts of the first and the second embodiments and the variations may be selectively used in any appropriate combination.

In the present embodiment, the third pad portion 131 of the third lead 13 does not extend to a position overlapping with the die pad portion 111 in the z direction and does not include portions corresponding to the bonded portion 131b and the connecting portion 131c of the first embodiment. Additionally, the semiconductor device A30 further includes a connecting member 32. The connecting member 32, which may be a bonding wire, is conductively bonded to the third lead obverse surface 1311 of the third pad portion 131 of the third lead 13 and the third electrode 203 of the semiconductor element 20. The material of the connecting member 32 is not limited and may include gold (Au), for example. The number of connecting members 32 is not limited, and a plurality of connecting members 32 may be provided. The connecting member 32 may be a metal plate (clip) containing a metal such as aluminum (Al), copper (Cu) or gold (Au), for example.

According to the present variation again, the semiconductor device A30 can be surface-mounted. As will be understood from the present embodiment, the specific configuration for conduction between the third lead 13 and the semiconductor element 20 is not limited. Incidentally, instead of connecting the third lead 13 and the semiconductor element 20 with the connecting member 32, the second lead 12 and the semiconductor element 20 may be connected with a connecting member.

### Fourth Embodiment

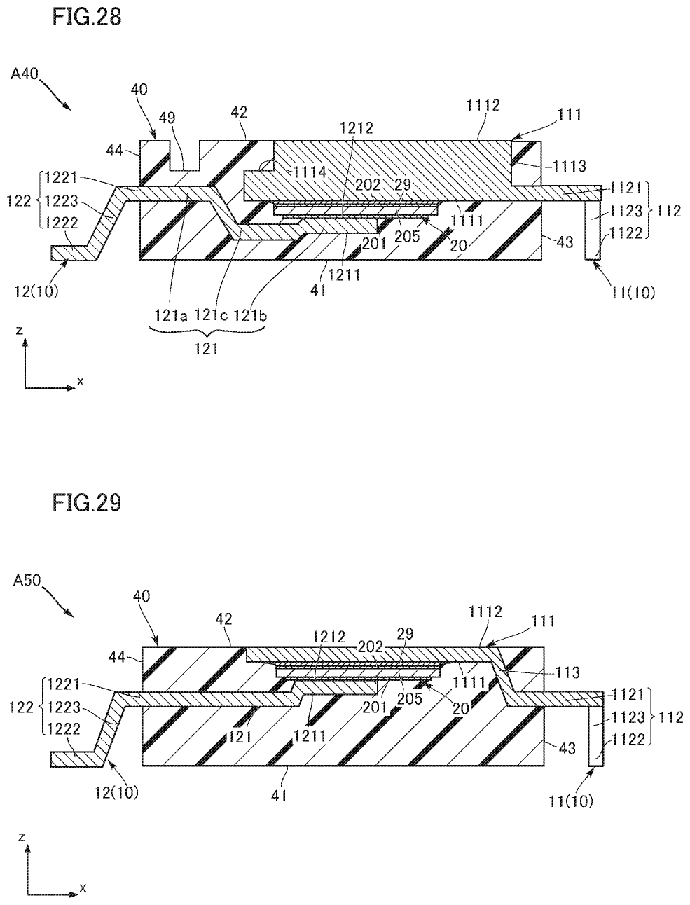

FIG. 28 shows a semiconductor device according to a fourth of embodiment the present disclosure. The semiconductor device A40 of the present embodiment differs from the above-described embodiments in shape of the second lead 12 and the third lead 13. The configuration and operation of other parts of the present embodiment are the same as those of the first embodiment. Incidentally, various parts of the first through the third embodiments and the variations may be selectively used in any appropriate combination.

In the second lead 12 of the present embodiment, the position of the fourth portion 1221 of the second terminal portion 122 in the z direction is the same as that of the first portion 1121 of the first terminal portion 112 of the first lead 11. Accordingly, the first penetration location of the third resin surface 43 by the first portion 1121 and the second penetration location of the fourth resin surface 44 by the fourth portion 1221 are at the same position in the z direction. The position of the main body 121a of the second pad portion 121 in the z direction is the same as that of the first portion 1121 of the first terminal portion 112. Therefore, the connecting portion 121c has a surface that is inclined with respect to the xy-plane in such a manner as to extend toward the first side in the z direction as proceeding from the main body 121a toward the first side in the x direction. Though not illustrated, the third lead 13 has the same configuration as the second lead 12. That is, the seventh portion 1321 is at the same position in the z direction as the first portion 1121, and the connecting portion 131c has an inclined surface similar to that of the connecting portion 121c.

According to the present variation again, the semiconductor device A40 can be surface-mounted. Additionally, the present embodiment allows the first penetration location of the third resin surface 43 by the first portion 1121 and the second penetration location of the fourth resin surface 44 by the fourth portion 1221 to be at the same position in the z direction.

### Fifth Embodiment

FIG. 29 shows a semiconductor device according to a fifth embodiment of the present disclosure. The semiconductor device A50 of the present embodiment differs from the above-described embodiments in configuration of the first lead 11.

The configuration and operation of other parts of the present embodiment are the same as those of the first embodiment. Incidentally, various parts of the first through the fourth embodiments and the variations may be selectively used in any appropriate combination.

In the first lead 11 of the present embodiment, the die pad portion 111 and the first portion 1121 have the same size in the z direction. The first lead 11 has a connecting portion 113. The connecting portion 113 connects the die pad portion 111 and the first portion 1121 of the first terminal portion 112. In the present embodiment again, the single first portion 1121 penetrates the third resin surface 43. In the present embodiment, the position in the z direction of the first lead obverse surface 1111 and the position in the z direction of the surface of the first portion 1121 that faces the first side in the z direction are different from each other. In the present embodiment, the first penetration location of the third resin surface 43 by the first portion 1121 and the second penetration location of the fourth resin surface 44 by the fourth portion 1221 are at the same position in the z direction.

According to present again, the variation the semiconductor device A50 can be surface-mounted. As will be understood from the present embodiment, the relationship between the size of the die pad portion 111 in the z direction and the size of the first portion 1121 in the z direction is not limited.

### Sixth Embodiment

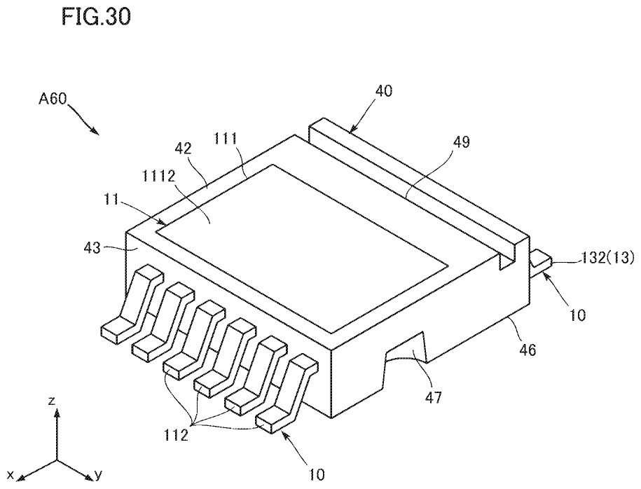

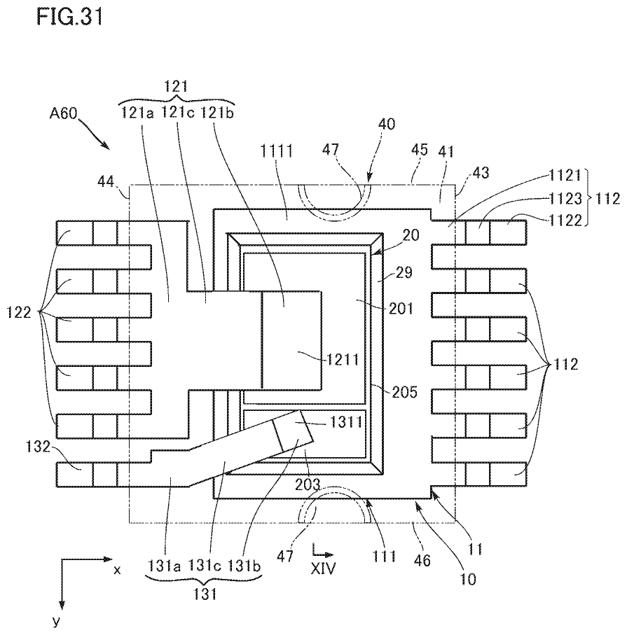

FIGS. 30 and 31 show a semiconductor device according to a sixth embodiment of the present disclosure. The semiconductor device A60 of the present embodiment differs from the above-described embodiments in configuration of the first terminal portion 112. The configuration and operation of other parts of the present embodiment are the same as those of the first embodiment. Incidentally, various parts of the first through the fifth embodiments and the variations may be selectively used in any appropriate combination.

The first lead 11 of the present embodiment has a plurality of first terminal portions 112. The first terminal portions 112 are arranged side by side in the y direction. Each of the first terminal portions 112 has a first portion 1121, a second portion 1122, and a third portion 1123.

The first portion 1121 is connected to the die pad portion 111. The first portion 1121 extends from the first lead side surface 1113 of the die pad portion 111 toward the first side in the x direction, and is parallel to the xy-plane in the illustrated example. The first portion 1121 penetrates the third resin surface 43. The shape of the first portion 1121 is not limited and is rectangular as viewed in the z direction in the illustrated example.

The second portion 1122 is located on the first side in the z direction with respect to the first portion 1121. The second portion 1122 is used in surface-mounting the semiconductor device A60 to a circuit board or the like. The second portion 1122 extends along the x direction.

The third portion 1123 is interposed between the first portion 1121 and the second portion 1122. The third portion 1123 extends from the first portion 1121 toward the first side in the z direction. In the illustrated example, the third portion 1123 is inclined with respect to the z direction (yz-plane). The shape of the third portion 1123 is not limited and is rectangular as viewed in the x direction in the illustrated example.

According to the present embodiment again, the semiconductor device A60 can be surface-mounted. The first lead 11 has a plurality of first terminal portions 112. This increases the mounting strength of the semiconductor device A60. As will be understood from the present embodiment, the configuration of the first terminal portion 112 is not limited.

### Sixth Embodiment, Variation

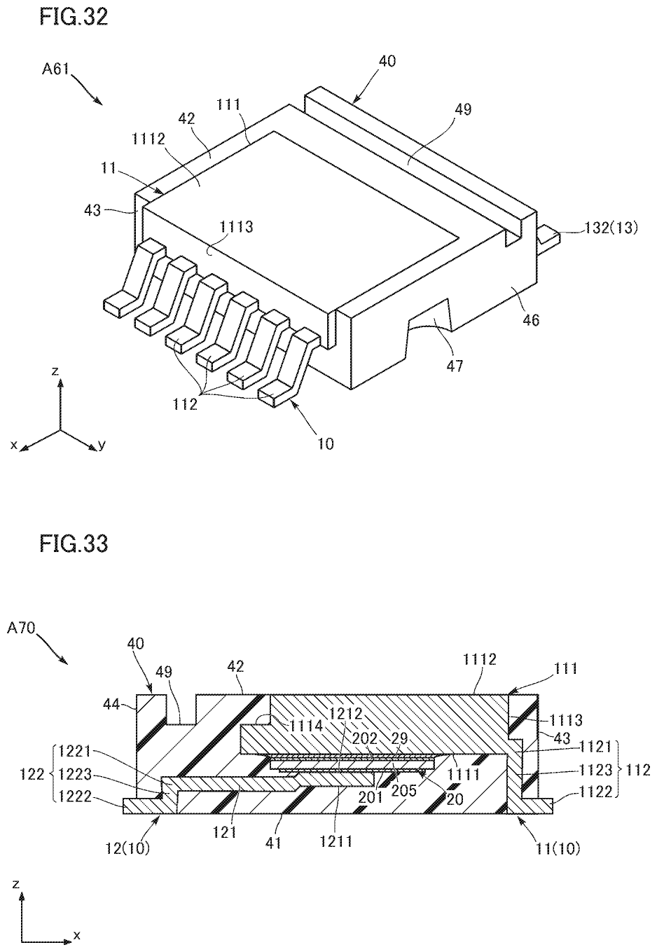

FIG. 32 shows a variation of the semiconductor device A60. In the semiconductor device A61 of the present variation, the first lead reverse surface 1112 has a portion protruding toward the first side in the x direction relative to the third resin surface 43 as viewed in the z direction. That is, in the present variation, the die pad portion 111 rather than the first portion 1121 penetrates the third resin surface 43.

According to the present variation again, the semiconductor device A61 can be surface-mounted, and the same effects as those of the above-described examples are provided. Additionally, because the first lead reverse surface 1112 has a portion protruding toward the first side in the x direction relative to the third resin surface 43, the area of the first lead reverse surface 1112 that faces the heat sink 91 is increased. As a result, the efficiency of heat dissipation from the semiconductor device A61 to the heat sink 91 is increased.

### Seventh Embodiment

FIG. 33 shows a semiconductor device according to a seventh embodiment of the present disclosure. The semiconductor device A70 of the present embodiment differs from the above-described embodiments in configuration of the first terminal portion 112, the second terminal portion 122, and the third terminal portion 132. The configuration and operation of other parts of the present embodiment are the same as those of the first embodiment. Incidentally, various parts of the first through the sixth embodiments and the variations may be selectively used in any appropriate combination.

In the first terminal portion 112 of the present embodiment, the first portion 1121 does not penetrate the third resin surface 43, the third portion 1123 extends in the z direction within the sealing resin 40, and the second portion 1122 is exposed from the first resin surface 41. Also, in the second terminal portion 122, the fourth portion 1221 does not penetrate the fourth resin surface 44, the sixth portion 1223 extends in the z direction within the sealing resin 40, and the fifth portion 1222 is exposed from the first resin surface 41. Also, though not shown in the figure, in the third terminal portion 132, the seventh portion 1321 does not penetrate the fourth resin surface 44, the ninth portion 1323 extends in the z direction within the sealing resin 40, and the eighth portion 1322 is exposed from the first resin surface 41.

According to the present embodiment again, the semiconductor device A70 can be surface-mounted. Additionally, the mounting area (dimension in the x direction) of the semiconductor device A70 can be reduced as compared with the case where the first terminal portion 112, the second terminal portion 122 and the third terminal portion 132 penetrate the third resin surface 43 or the fourth resin surface 44 to protrude in the x direction. As will be understood from the present embodiment, the configurations of the first terminal portion 112, the second terminal portion 122 and the third terminal portion 132 are not limited.

### Seventh Embodiment, Variation

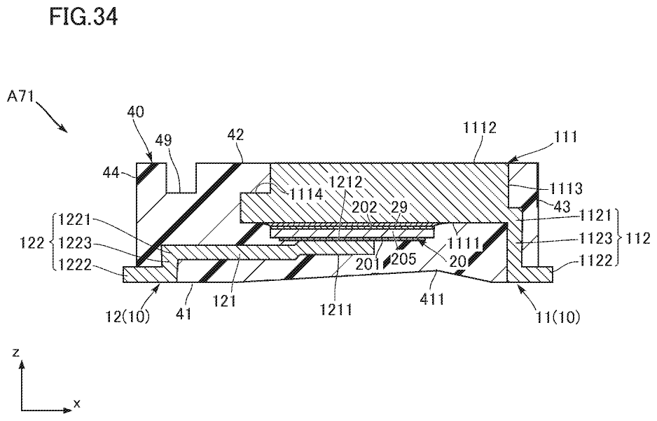

FIG. 34 shows a variation of the semiconductor device A70. In the semiconductor device A71 of the present variation, the sealing resin 40 has a recessed region 411. The recessed region 411 is the region that is recessed from the first resin surface 41 in the z direction. The recessed region 411 is located between the second portion 1122 and the fifth and the eighth portions 1222 and 1322 in the x direction. In the present variation, the recessed region 411 is gently recessed toward the second side in the z direction as proceeding from the edge close to the second portion 1122 toward the second side in the x direction and gently recessed toward the second side in the z direction as proceeding from the edge close to the fifth portion 1222 and the eighth portion 1322 toward the first side in the x direction. The recessed region 411 is formed so as not to affect the second pad portion 121, the third pad portion 131 and the semiconductor element 20.

According to the present variation again, the semiconductor device A71 can be surface-mounted, and the same effects as those of the above-described examples are provided. Additionally, because the sealing resin 40 has the recessed region 411, the distance along the surface of the sealing resin 40 (creepage distance) from the second portion 1122 to the fifth portion 1222 and the eighth portion 1322 is increased. Incidentally, the recessed region 411 is not limited to the region with only one gentle recess as in the present variation. The recessed region 411 may have a plurality of recesses.

The semiconductor device according to the present disclosure is not limited to the above-described embodiments. Various modifications in design may be made freely in the specific structure of each part of the semiconductor device according to the present disclosure. The present disclosure includes embodiments described in the following clauses.

### Clause 1.

A semiconductor device comprising:
a semiconductor element;
a first lead including a die pad portion and a first terminal portion, the die pad portion including a first lead obverse surface which faces a first side in a thickness direction and on which the semiconductor element is mounted, and the die pad portion including a first lead reverse surface facing a second side in the thickness direction;
a second lead spaced apart from the first lead; and
a sealing resin including a first resin surface facing the first side in the thickness direction and a second resin surface facing the second side in the thickness direction, the sealing resin covering the semiconductor element and a part of the die pad portion, wherein
the first lead reverse surface is exposed from the second resin surface,
the second includes lead a second pad portion conductively bonded to the semiconductor element and a second terminal portion connected to the second pad portion, and
the second terminal portion includes a fourth portion connected to the second pad portion, and a fifth portion located on the first side in the thickness direction with respect to the fourth portion and used for mounting.

### Clause 2.

The semiconductor device according to clause 1, wherein the sealing resin includes a third resin surface facing a first side in a first direction orthogonal to the thickness direction and a fourth resin surface facing a second side in the first direction.

### Clause 3.

The semiconductor device according to clause 2, wherein the first terminal portion includes a first portion connected to the die pad portion, a second portion located on the first side in the thickness direction with respect to the first portion and used for mounting, and a third portion interposed between the first portion and the second portion.

### Clause 4.

The semiconductor device according to clause 3, wherein the first portion penetrates the third resin surface and is spaced apart from the second resin surface in the thickness direction, and
the fourth portion penetrates the fourth resin surface and is spaced apart from the second resin surface in the thickness direction.

### Clause 5.

The semiconductor device according to clause 4, wherein the second portion extends from the third portion outward in a second direction orthogonal to the thickness direction and the first direction.

### Clause 6.

The semiconductor device according to clause 4 or 5, wherein a first penetration location of the third resin surface by the first portion and a second penetration location of the fourth resin surface by the fourth portion are at a same position in the thickness direction.

### Clause 7.

The semiconductor device according to any one of clauses 4 to 6, wherein a surface of the second portion that faces the first side in the thickness direction and a surface of the fifth portion that faces the first side in the thickness direction are located on the second side in the thickness direction from the first resin surface.

### Clause 8.

The semiconductor device according to any one of clauses 4 to 7, wherein the die pad portion is larger than the first portion of the first terminal portion in size in the thickness direction, and
a surface of the first portion on the first side in the thickness direction is flush with the first lead obverse surface.

### Clause 9.

The semiconductor device according to clause 3, wherein the second terminal portion includes a sixth portion interposed between the fourth portion and the fifth portion,
the third portion and the sixth portion extend in the thickness direction within the sealing resin, and
the second portion and the fifth portion are exposed from the first resin surface.

### Clause 10.

The semiconductor device according to clause 9, wherein the sealing resin includes a recess that is recessed from the first resin surface in the thickness direction at a location between the second portion and the fifth portion in the first direction.

### Clause 11.

The semiconductor device according to any one of clauses 1 to 10, further comprising a third lead spaced apart from the first lead and the second lead, wherein
the third lead includes a third pad portion and a third terminal portion connected to the third pad portion, and
the third terminal portion includes a seventh portion connected to the third pad portion, an eighth portion located on the first side in the thickness direction with respect to the seventh portion and used for mounting, and a ninth portion interposed between the seventh portion and the eighth portion.

### Clause 12.

The semiconductor device according to clause 11, wherein the third pad portion is conductively bonded to the semiconductor element.

### Clause 13.

The semiconductor device according to clause 11, further comprising a connecting member conductively bonded to the third pad portion and the semiconductor element.

### Clause 14.

The semiconductor device according to any one of clauses 1 to 13, wherein the sealing resin includes a groove recessed from the second resin surface in the thickness direction.

### Clause 15.

The semiconductor device according to any one of clauses 1 to 13, wherein the sealing resin includes a protrusion that protrudes from the second resin surface in the thickness direction.

### REFERENCE NUMERALS

A10, A11, A12, A13, A14: Semiconductor device
A15, A16, A20, A30, A40: Semiconductor device
A50, A60, A61, A70, A71: Semiconductor device
10: Conductive member
11: First lead
12: Second lead
13: Third lead
14: Fourth lead
20: Semiconductor element
29: Bonding layer
32: Connecting member
40: Sealing resin
41: First resin surface
42: Second resin surface
43: Third resin surface
44: Fourth resin surface
45: Fifth resin surface
46: Sixth resin surface
47: Recess
48: Protrusion
49: Groove
91: Heat sink
92: Circuit board
111: Die pad portion
112: First terminal portion
113: Connecting portion
121: Second pad portion
121a: Main body
121b: Bonded portion
121c: Connecting portion
131: Third pad portion
131a: Main body
131b: Bonded portion
131c: Connecting portion
132: Third terminal portion
141: Fourth pad portion
142: Fourth terminal portion
201: First electrode
202: Second electrode
203: Third electrode
205: Semiconductor layer
411: Recessed region
919: Sheet material
921: Solder
1111: First lead obverse surface
1112: First lead reverse surface
1113: First lead side surface
1114: First intermediate surface
1121: First portion
1122: Second portion
1123: Third portion
1211: Second lead obverse surface
1212: Second lead reverse surface
1221: Fourth portion
1222: Fifth portion
1223: Sixth portion
1311: Third lead obverse surface
1312: Third lead reverse surface
1321: Seventh portion
1322: Eighth portion
1323: Ninth portion
1411: Fourth lead obverse surface
1412: Fourth lead reverse surface

1. A semiconductor device comprising:
a semiconductor element;
a first lead including a die pad portion and a first terminal portion, the die pad portion including a first lead obverse surface which faces a first side in a thickness direction and on which the semiconductor element is mounted, and the die pad portion including a first lead reverse surface facing a second side in the thickness direction;
a second lead spaced apart from the first lead; and
a sealing resin including a first resin surface facing the first side in the thickness direction and a second resin surface facing the second side in the thickness direction, the sealing resin covering the semiconductor element and a part of the die pad portion, wherein
the first lead reverse surface is exposed from the second resin surface,
a second pad portion the second lead includes conductively bonded to the semiconductor element and a second terminal portion connected to the second pad portion, and
the second terminal portion includes a fourth portion connected to the second pad portion, and a fifth portion located on the first side in the thickness direction with respect to the fourth portion and used for mounting.

2. The semiconductor device according to claim 1, wherein the sealing resin includes a third resin surface facing a first side in a first direction orthogonal to the thickness direction and a fourth resin surface facing a second side in the first direction.

3. The semiconductor device according to claim 2, wherein the first terminal portion includes a first portion connected to the die pad portion, a second portion located on the first side in the thickness direction with respect to the first portion and used for mounting, and a third portion interposed between the first portion and the second portion.

4. The semiconductor device according to claim 3, wherein the first portion penetrates the third resin surface and is spaced apart from the second resin surface in the thickness direction, and
the fourth portion penetrates the fourth resin surface and is spaced apart from the second resin surface in the thickness direction.

5. The semiconductor device according to claim 4, wherein the second portion extends from the third portion outward in a second direction orthogonal to the thickness direction and the first direction.

6. The semiconductor device according to claim 4, wherein a first penetration location of the third resin surface by the first portion and a second penetration location of the fourth resin surface by the fourth portion are at a same position in the thickness direction.

7. The semiconductor device according to claim 4, wherein a surface of the second portion that faces the first side in the thickness direction and a surface of the fifth portion that faces the first side in the thickness direction are located on the second side in the thickness direction from the first resin surface.

8. The semiconductor device according to claim 4, wherein the die pad portion is larger than the first portion of the first terminal portion in size in the thickness direction, and
a surface of the first portion on the first side in the thickness direction is flush with the first lead obverse surface.

9. The semiconductor device according to claim 3, wherein the second terminal portion includes a sixth portion interposed between the fourth portion and the fifth portion,
the third portion and the sixth portion extend in the thickness direction within the sealing resin, and
the second portion and the fifth portion are exposed from the first resin surface.

10. The semiconductor device according to claim 9, wherein the sealing resin includes a recess that is recessed from the first resin surface in the thickness direction at a location between the second portion and the fifth portion in the first direction.

11. The semiconductor device according to claim 1, further comprising a third lead spaced apart from the first lead and the second lead, wherein
the third lead includes a third pad portion and a third terminal portion connected to the third pad portion, and
the third terminal portion includes a seventh portion connected to the third pad portion, an eighth portion located on the first side in the thickness direction with respect to the seventh portion and used for mounting, and a ninth portion interposed between the seventh portion and the eighth portion.

12. The semiconductor device according to claim 11, wherein the third pad portion is conductively bonded to the semiconductor element.

13. The semiconductor device according to claim 11, further comprising a connecting member conductively bonded to the third pad portion and the semiconductor element.

14. The semiconductor device according to claim 1, wherein the sealing resin includes a groove recessed from the second resin surface in the thickness direction.

15. The semiconductor device according to claim 1, wherein the sealing resin includes a protrusion that protrudes from the second resin surface in the thickness direction.
